(19) United States
(12) Patent Application Publication
(10) Pub. No.: US 2025/0063905 A1
(43) Pub. Date: Feb. 20, 2025

(54) DISPLAY DEVICE

(71) Applicant: Samsung Display Co., LTD., Yongin-si (KR)

(72) Inventors: JUNYOUNG MIN, Yongin-si (KR); JUN-YONG AN, Yongin-si (KR); JUNWON CHOI, Yongin-si (KR)

(21) Appl. No.: 18/742,635

(22) Filed: Jun. 13, 2024

(30) Foreign Application Priority Data
Aug. 18, 2023 (KR) 10-2023-0108250

(51) Int. Cl. H10K 59/131; H10K 59/35; H10K 59/80

(52) U.S. Cl. CPC H10K 59/131; H10K 59/352; H10K 59/80515

(57) ABSTRACT

A display device includes a first sub-pixel including a first pixel circuit portion including a first active pattern, a first-first gate electrode of a first driving transistor, and a first connection pattern connected to the first-first gate electrode, and a first light-emitting element electrically connected to the first pixel circuit portion, and including a first pixel electrode, a first light-emitting layer, and a first common electrode, and a second sub-pixel adjacent to the first sub-pixel in a first direction, and including a second pixel circuit portion including a second active pattern, a first-second gate electrode of a second driving transistor, and a second connection pattern connected to the first-second gate electrode and not overlapping the first pixel electrode in plan view, and a second light-emitting element electrically connected to the second pixel circuit portion, and including a second pixel electrode, a second light-emitting layer, and a second common electrode.

### CROSS-REFERENCE TO RELATED APPLICATION

The present application claims priority to, and the benefit of, Korean Patent Application No. 10-2023-0108250, filed on Aug. 18, 2023, in the Korean Intellectual Property Office, the entire disclosure of which is incorporated herein by reference.

### BACKGROUND

### 1. Technical Field

Embodiments relate to a display device that provides visual information.

### 2. Description of the Related Art

As information technology develops, the importance of display devices, which are communication media between users and information, is being highlighted. Accordingly, the use of display devices, such as a liquid crystal display device, an organic light emitting display device, a plasma display device, and the like is increasing.

### SUMMARY

Embodiments provide a display device with improved display quality.

A display device according to embodiments of the present disclosure includes a first sub-pixel including a first pixel circuit portion including a first active pattern, a first-first gate electrode of a first driving transistor partially overlapping the first active pattern, and a first connection pattern connected to the first-first gate electrode, and a first light-emitting element electrically connected to the first pixel circuit portion, and including a first pixel electrode, a first light-emitting layer, and a first common electrode, and a second sub-pixel adjacent to the first sub-pixel in a first direction, and including a second pixel circuit portion including a second active pattern, a first-second gate electrode of a second driving transistor partially overlapping the second active pattern, and a second connection pattern connected to the first-second gate electrode and not overlapping the first pixel electrode in plan view, and a second light-emitting element electrically connected to the second pixel circuit portion, and including a second pixel electrode, a second light-emitting layer, and a second common electrode.

The first pixel electrode may have a quadrilateral shape having a recessed corner part in plan view.

The second pixel electrode may be adjacent to the first pixel electrode in a second direction crossing the first direction.

The first pixel circuit portion may further include a first lower conductive pattern under the first active pattern, and partially overlapping the first active pattern in plan view, wherein the second pixel circuit portion further includes a second lower conductive pattern at a same layer as the first lower conductive pattern, and partially overlapping the second active pattern in plan view, wherein a part of the first active pattern overlapping the first lower conductive pattern constitutes a first storage capacitor, and wherein a part of the second active pattern overlapping the second lower conductive pattern constitutes a second storage capacitor.

The first active pattern may define a first through hole exposing a part of the first lower conductive pattern, wherein the second active pattern defines a second through hole exposing a part of the second lower conductive pattern, wherein the first connection pattern is connected to the first lower conductive pattern through a first contact hole overlapping the first through hole, and wherein the second connection pattern is connected to the second lower conductive pattern through a second contact hole overlapping the second through hole.

The display device may further include a first data line configured to receive a first data voltage, extending in a second direction crossing the first direction, and overlapping a first overlapping part of the first active pattern extending in the second direction in plan view, and a second data line at a same layer as the first data line, configured to receive a second data voltage, extending in the second direction, and overlapping a second overlapping part of the second active pattern extending in the second direction in plan view.

The first overlapping part might not overlap the first lower conductive pattern in plan view, wherein the second overlapping part does not overlap the second lower conductive pattern in plan view.

The first and second data lines may be at a same layer as the first and second connection patterns.

The second active pattern may be symmetrical to the first active pattern.

The second connection pattern may be symmetrical to the first connection pattern.

The first pixel electrode may partially overlap the second pixel circuit portion in plan view, wherein the second pixel electrode partially overlaps the first pixel circuit portion in plan view.

The first pixel electrode may at least partially overlap the first connection pattern in plan view.

The display device may further include a driving voltage line under the first and second active patterns, configured to receive a driving voltage, and extending in the first direction, wherein in the first pixel circuit portion, a part of the first active pattern constitutes a first hold capacitor together with a part of the driving voltage line, and wherein in the second pixel circuit portion, a part of the second active pattern constitutes a second hold capacitor together with a part of the driving voltage line.

The first-first gate electrode may be configured to receive a first data voltage through the first connection pattern, wherein the first-second gate electrode is configured to receive a second data voltage through the second connection pattern.

The first light-emitting layer and the second light-emitting layer may include light-emitting materials configured to emit light of different respective colors.

Each of the first and second active patterns may include a metal oxide semiconductor.

A display device according to embodiments of the present disclosure include a first active pattern above a substrate, a second active pattern at a same layer as the first active pattern, a first-first gate electrode of a first transistor above the first active pattern, a first-second gate electrode of a second transistor at a same layer as the first-first gate electrode, a first connection pattern above the first-first gate electrode, and connected to the first-first gate electrode, a second connection pattern at a same layer as the first connection pattern, and connected to the first-second gate electrode, a first pixel electrode above the first connection pattern, and not overlapping the second connection pattern in plan view, and a second pixel electrode above the second connection pattern.

The first pixel electrode may have a quadrilateral shape including a corner part that is recessed in plan view.

The display device may further include a first lower conductive pattern under the first active pattern, and partially overlapping the first active pattern in plan view, and a second lower conductive pattern at a same layer as the first lower conductive pattern, and partially overlapping the second active pattern in plan view, wherein a part of the first active pattern overlapping the first lower conductive pattern constitutes a first storage capacitor, and wherein a part of the second active pattern overlapping the second lower conductive pattern constitutes a second storage capacitor.

The first active pattern may define a first through hole exposing at least a part of the first lower conductive pattern, wherein the second active pattern defines a second through hole exposing at least a part of the second lower conductive pattern, wherein the first connection pattern is connected to the first lower conductive pattern through a first contact hole overlapping the first through hole, and wherein the second connection pattern is connected to the second lower conductive pattern through a second contact hole overlapping the second through hole.

The display device may further include a first data line configured to receive a first data voltage, extending in one direction, and overlapping a first overlapping part of the first active pattern extending in the one direction in plan view, and a second data line at a same layer as the first data line, configured to receive a second data voltage, extending in the one direction, and overlapping a second overlapping part of the second active pattern extending in the one direction in plan view.

The first overlapping part might not overlap the first lower conductive pattern in plan view, wherein the second overlapping part does not overlap the second lower conductive pattern in plan view.

The second active pattern may be symmetrical to the first active pattern, wherein the second active pattern is symmetrical to the first active pattern.

The first pixel electrode may at least partially overlap the first connection pattern in plan view.

The display device may further include a driving voltage line under the first and second active patterns, configured to receive a driving voltage, and extending in one direction, wherein a part of the first active pattern constitutes a first hold capacitor together with a part of the driving voltage line, and wherein a part of the second active pattern constitutes a second hold capacitor together with another part of the driving voltage line.

The display device may further include a first light-emitting layer above the first pixel electrode, and a second light-emitting layer above the second pixel electrode, wherein the first light-emitting layer and the second light-emitting layer include light-emitting materials configured to emit light of different respective colors.

The first-first gate electrode may be configured to receive a first data voltage through the first connection pattern, wherein the first-second gate electrode is configured to receive a second data voltage through the second connection pattern.

In a display device according to embodiments of the present disclosure, a first pixel electrode of a first light-emitting element included in a first sub-pixel might not overlap a driving gate node connected to a gate electrode of a driving transistor included in a second sub-pixel that is adjacent to the first sub-pixel in a plan view. The first and second sub-pixels may emit light of different respective colors. A formation of a parasitic capacitor between the first pixel electrode of the first light-emitting element included in the first sub-pixel, and the driving gate node connected to the gate electrode of the driving transistor included in the second sub-pixel, can be minimized or reduced. In this case, defects, such as stains, can be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a circuit diagram illustrating first and second sub-pixels of FIG. 1.

FIG. 3 is a cross-sectional view illustrating an example of the display device of FIG. 1.

FIG. 4 is a layout view illustrating a circuit layer of FIG. 3.

FIGS. 5, 6, 7, 8, 9, and 10 are layout views for explaining components illustrated in the layout view of FIG. 4 by layer.

FIG. 11 is a layout view illustrating first, second, and third light-emitting elements of a display device according to one or more embodiments of the present disclosure.

FIG. 12 is a layout view illustrating first, second, and third light-emitting elements of a display device according to one or more other embodiments of the present disclosure.

FIG. 13 is a layout view illustrating first, second, and third light-emitting elements of a display device according to still one or more other embodiments of the present disclosure.

FIG. 14 is a layout view illustrating first, second, and third light-emitting elements located on first, second, and third pixel circuits of FIG. 4.

FIG. 15 is a cross-sectional view taken along the line I-I′ of FIG. 4.

FIG. 16 is a cross-sectional view taken along the line II-II′ of FIG. 4.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

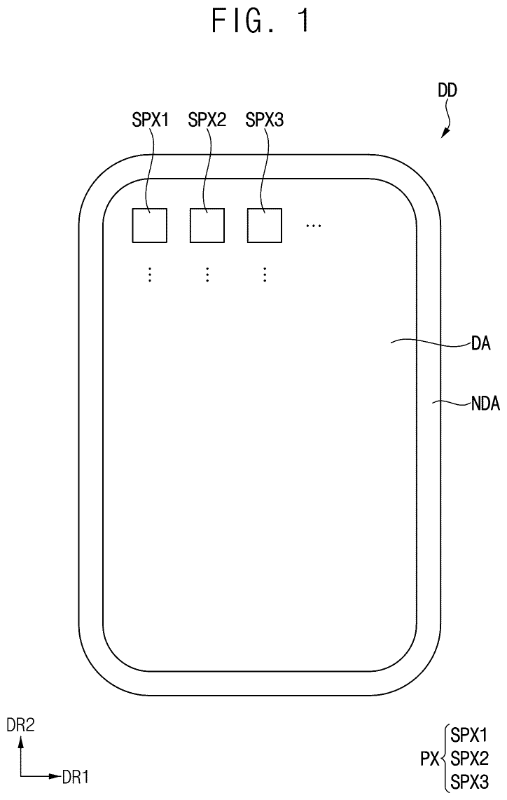

FIG. 1 is a plan view illustrating a display device according to one or more embodiments of the present disclosure.

Referring to FIG. 1, a display device DD according to one or more embodiments of the present disclosure may be divided into a display area DA and a non-display area NDA. The display area DA may be an area that can display an image by generating light, or by adjusting the transmittance of light provided from an external light source. The non-display area NDA may be an area that does not display images. The non-display area NDA may be located around the display area DA. For example, the non-display area NDA may surround the display area DA.

The display device DD may have a rectangular planar shape with rounded corners. However, embodiments of the present disclosure are not limited to this, and the display device DD may have various planar shapes in a plan view.

A plurality of pixels PX may be located in the display area DA. As the plurality of pixels PX emit light, the display area DA may display an image.

Each of the plurality of pixels PX may include a first sub-pixel SPX1, a second sub-pixel SPX2, and a third sub-pixel SPX3. In one or more embodiments, the first sub-pixel SPX1 may be a red sub-pixel that emits red light, the second sub-pixel SPX2 may be a green sub-pixel that emits green light, and the third sub-pixel SPX3 may be a green sub-pixel that emits blue light. However, the color of light emitted by the first, second, and third sub-pixels SPX1, SPX2, and SPX3 is not limited to this. In addition, the number of first, second, and third sub-pixels SPX1, SPX2, and SPX3 is shown as three, but the number is not limited thereto. For example, each of the plurality of pixels PX may further include a fourth sub-pixel that emits white light.

The plurality of pixels PX may be located in a matrix form along a first direction DR1, and along a second direction DR2 crossing the first direction DR1. Accordingly, each of the first sub-pixel SPX1, the second sub-pixel SPX2, and the third sub-pixel SPX3 may be arranged in a matrix form along the first direction DR1 and the second direction DR2.

Pixel drivers may be located in the non-display area NDA. For example, the pixel drivers may include a gate driver, a data driver, and the like. The pixel drivers may be electrically connected to the plurality of pixels PX. The pixel drivers may provide signals and voltages for emitting light to the plurality of pixels PX.

In this specification, a plane may be defined as the first direction DR1, and the second direction DR2 crossing the first direction DR1. For example, the first direction DR1 may be perpendicular to the second direction DR2.

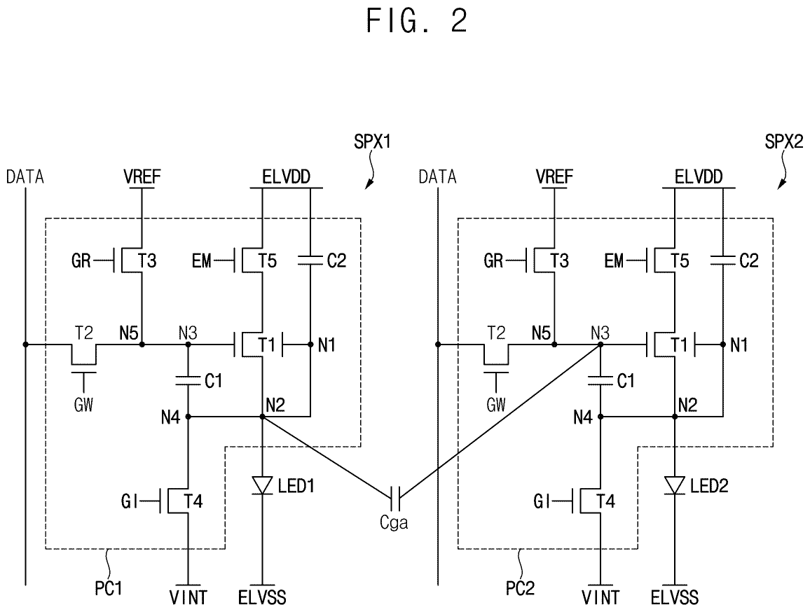

FIG. 2 is a circuit diagram illustrating first and second sub-pixels of FIG. 1.

Referring to FIG. 2, the first sub-pixel SPX1 may include a first pixel circuit PC1, and a first light-emitting element LED1 electrically connected to the first pixel circuit PC1. The second sub-pixel SPX2 may include a second pixel circuit PC2, and a second light-emitting element LED2 electrically connected to the second pixel circuit PC2. The third sub-pixel SPX3 may have a circuit structure that is substantially the same as a circuit structure of each of the first and second sub-pixels SPX1 and SPX2.

The first pixel circuit PC1 may provide a driving current to the first light-emitting element LED1, and the first light-emitting element LED1 may generate light based on the driving current. In addition, the second pixel circuit PC2 may provide a driving current to the second light-emitting element LED2, and the second light-emitting element LED2 can generate light based on the driving current.

Each of the first pixel circuit PC1 and the second pixel circuit PC2 may include a first transistor T1, a second transistor T2, a third transistor T3, a fourth transistor T4, a fifth transistor T5, a first capacitor C1, and a second capacitor C2.

The first transistor T1 may include a back gate electrode, a gate electrode, a first electrode, and a second electrode. The back gate electrode of the first transistor T1 may be connected to a first node N1. The gate electrode of the first transistor T1 may be connected to a third node N3. The first electrode of the first transistor T1 may be connected to a second electrode of the fifth transistor T5. The second electrode of the first transistor T1 may be connected to a second node N2. The first transistor T1 may generate the driving current based on the voltage difference between the gate electrode and the first electrode. For example, the first transistor T1 may be referred to as a driving transistor.

The second transistor T2 may include a gate electrode, a first electrode, and a second electrode. A first gate signal GW may be applied to the gate electrode of the second transistor T2. A data voltage DATA may be applied to the first electrode of the second transistor T2. The second electrode of the second transistor T2 may be connected to a fifth node N5 (e.g., to the third node N3).

The second transistor T2 may supply the data voltage DATA to the gate electrode of the first transistor T1 during an activation period of the first gate signal GW. Conversely, the second transistor T2 may block the supply of the data voltage DATA during a deactivation period of the first gate signal GW.

The third transistor T3 may include a gate electrode, a first electrode, and a second electrode. A second gate signal GR may be applied to the gate electrode of the third transistor T3. A reference voltage VREF may be applied to the first electrode of the third transistor T3. The second electrode of the third transistor T3 may be connected to the fifth node N5 (e.g., to the third node N3).

The third transistor T3 may supply the reference voltage VREF to the fifth node N5 during an activation period of the second gate signal GR. Conversely, the third transistor T3 may block the supply of the reference voltage VREF during a deactivation period of the second gate signal GR.

The fourth transistor T4 may include a gate electrode, a first electrode, and a second electrode. A third gate signal GI may be applied to the gate electrode of the fourth transistor T4. An initialization voltage VINT may be applied to the first electrode of the fourth transistor T4. The second electrode of the fourth transistor T4 may be connected to a fourth node N4 (e.g., to the second node N2).

The fourth transistor T4 may supply the initialization voltage VINT to the fourth node N4 during an activation period of the third gate signal GI. Conversely, the fourth transistor T4 may block the supply of the initialization voltage VINT during a deactivation period of the third gate signal GI.

The fifth transistor T5 may include a gate electrode, a first electrode, and a second electrode. A light-emitting control signal EM may be applied to the gate electrode of the fifth transistor T5. A driving voltage ELVDD may be applied to the first electrode of the fifth transistor T5. The second electrode of the fifth transistor T5 may be connected to the first electrode of the first transistor T1.

The fifth transistor T5 may supply the driving voltage ELVDD to the first electrode of the first transistor T1 during an activation period of the light-emitting control signal EM. Conversely, the fifth transistor T5 may block the supply of the driving voltage ELVDD during a deactivation period of the light-emitting control signal EM.

The first capacitor C1 may include a first electrode and a second electrode. The first electrode of the first capacitor C1 may be connected to the third node N3 (e.g., to the fifth node N5). The second electrode of the first capacitor C1 may be connected to the fourth node N4 (e.g., to the second node N2). The first capacitor C1 may maintain the voltage level of the gate electrode of the first transistor T1 during the deactivation period of the first gate signal GW. The first capacitor C1 may be referred to as a storage capacitor.

The second capacitor C2 may include a first electrode and a second electrode. The driving voltage ELVDD may be applied to the first electrode of the second capacitor C2. The second electrode of the second capacitor C2 may be connected to the first node N1. The second capacitor C2 may be referred to as a hold capacitor.

Each of the first and second light-emitting elements LED1 and LED2 may include a first electrode (e.g., an anode electrode) and a second electrode (e.g., a cathode electrode). The first electrode of each of the first and second light-emitting elements LED1 and LED2 may be connected to the corresponding second node N2. A common voltage ELVSS may be applied to the second electrode of each of the first and second light-emitting elements LED1 and LED2.

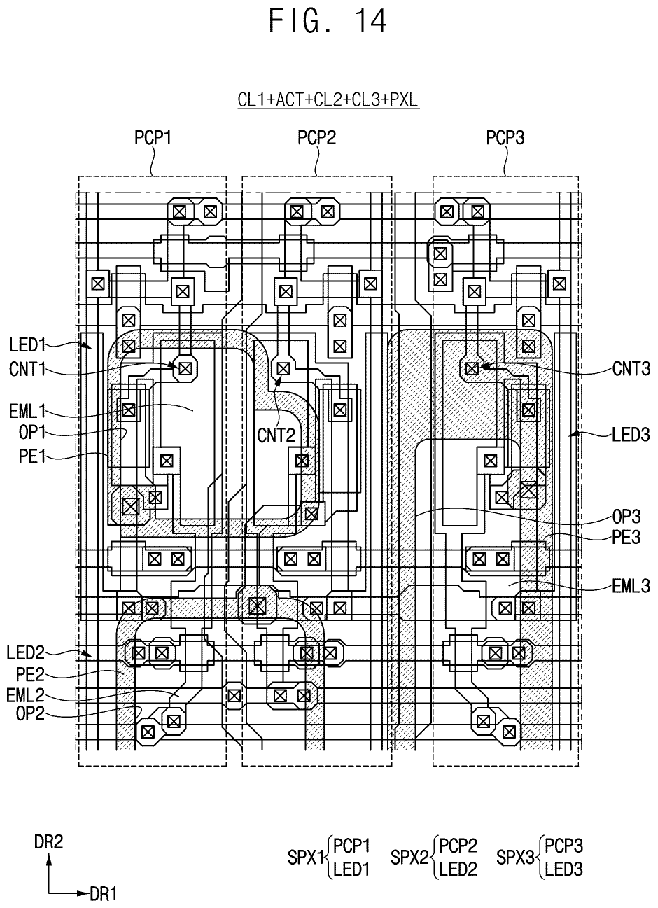

A parasitic capacitor Cga may be formed between the second node N2 of the first pixel circuit PC1 and the third node N3 of the second pixel circuit PC2 located adjacent to the first pixel circuit PC1. However, when the first, second, and third sub-pixels SPX1, SPX2, and SPX3 have the structure of the first, second, and third sub-pixels SPX1, SPX2, and SPX3 shown in FIG. 14, the formation of the parasitic capacitor Cga can be minimized or reduced. A detailed description of this will be provided later.

In one or more embodiments, each of the first, second, third, fourth, and fifth transistors T1, T2, T3, T4, and T5 may be an NMOS transistor. That is, an active pattern of each of the first, second, third, fourth, and fifth transistors T1, T2, T3, T4, and T5 may include a metal oxide semiconductor.

Meanwhile, the circuit structures of the first and second sub-pixels SPX1 and SPX2 shown in FIG. 2 are illustrative and may be changed in various ways.

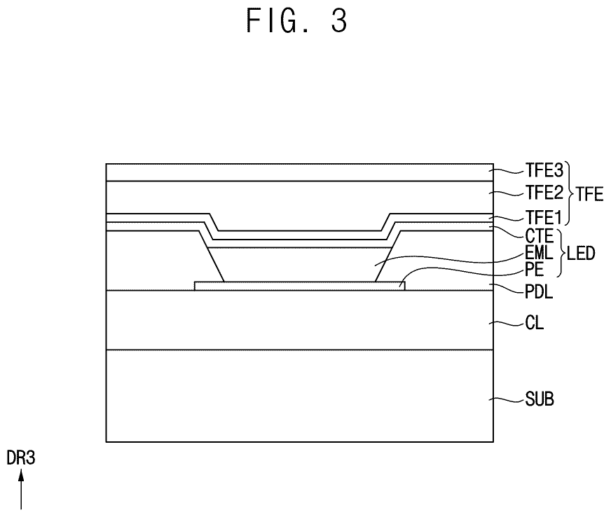

FIG. 3 is a cross-sectional view illustrating an example of the display device of FIG. 1. For example, FIG. 3 is a cross-sectional view illustrating a part of the display area DA of FIG. 1.

Referring to FIG. 3, the display device DD according to one or more embodiments of the present disclosure may include a substrate SUB, a circuit layer CL, a light-emitting element LED, a pixel-defining layer PDL, and an encapsulation layer TFE.

The substrate SUB may include a transparent material or an opaque material. The substrate SUB may be made of a transparent resin substrate. Examples of the transparent resin substrate may include a polyimide substrate. In this case, the polyimide substrate may include a first organic layer, a first barrier layer, a second organic layer, and/or the like. Alternatively, the substrate SUB may include a quartz substrate, a synthetic quartz substrate, a calcium fluoride substrate, a fluorine-doped quartz substrate, a soda-lime glass substrate, non-alkali glass substrate, and/or the like. These can be used alone or in combination with each other.

The circuit layer CL may be located on the substrate SUB. The circuit layer CL may provide signals and voltages for the light-emitting element LED to emit light to the light-emitting element LED. For example, the circuit layer CL may include a transistor, a conductive layer, an insulating layer, and/or the like.

The pixel electrode PE may be located on the circuit layer CL. The pixel electrode PE may receive the signals and voltages from the circuit layer CL. For example, the pixel electrode PE may include metal, alloy, metal nitride, conductive metal oxide, transparent conductive material, and/or the like. These can be used alone or in combination with each other. For example, the pixel electrode PE may be an anode electrode. Alternatively, the pixel electrode PE may be a cathode electrode.

The pixel-defining layer PDL may be located on the circuit layer CL and the pixel electrode PE (e.g., on one or more portions of the pixel electrode PE). The pixel-defining layer PDL may define an opening exposing at least a part of an upper surface of the pixel electrode PE. As the pixel-defining layer PDL defines the opening, the pixel-defining layer PDL may define each sub-pixel (e.g., the first, second, and third sub-pixels SPX1, SPX2, and SPX3 of FIG. 1) that emits light. The pixel-defining layer PDL may include organic materials and/or inorganic materials. Examples of the organic material that can be used as a pixel-defining layer PDL may include photoresist, polyacrylic resin, polyimide resin, polyamide resin, siloxane resin, acrylic resin, epoxy resin, and/or the like. These can be used alone or in combination with each other.

The emitting layer EML may be located on the pixel electrode PE. For example, the light-emitting layer EML may be located in the opening of the pixel-defining layer PDL. The light-emitting layer EML may include an organic light-emitting material to emit light.

The common electrode CTE may be located on the pixel-defining layer PDL and the emitting layer EML. For example, the common electrode CTE may include metal, alloy, metal nitride, conductive metal oxide, transparent conductive material, and/or the like. These can be used alone or in combination with each other. For example, the common electrode CTE may be a cathode electrode. Alternatively, the common electrode CTE may be an anode electrode.

Accordingly, a light-emitting element LED including the pixel electrode PE, the light-emitting layer EML, and the common electrode CTE may be located on the substrate SUB.

The encapsulation layer TFE may be located on the common electrode CTE. The encapsulation layer TFE can protect the light-emitting element LED from external oxygen and moisture. The encapsulation layer TFE may include at least one inorganic layer and at least one organic layer. For example, the encapsulation layer TFE a first inorganic layer TFE1 located on the common electrode CTE, an organic layer TFE2 located on the first inorganic layer TFE1, and a second inorganic layer TFE3 located on the organic layer TFE2.

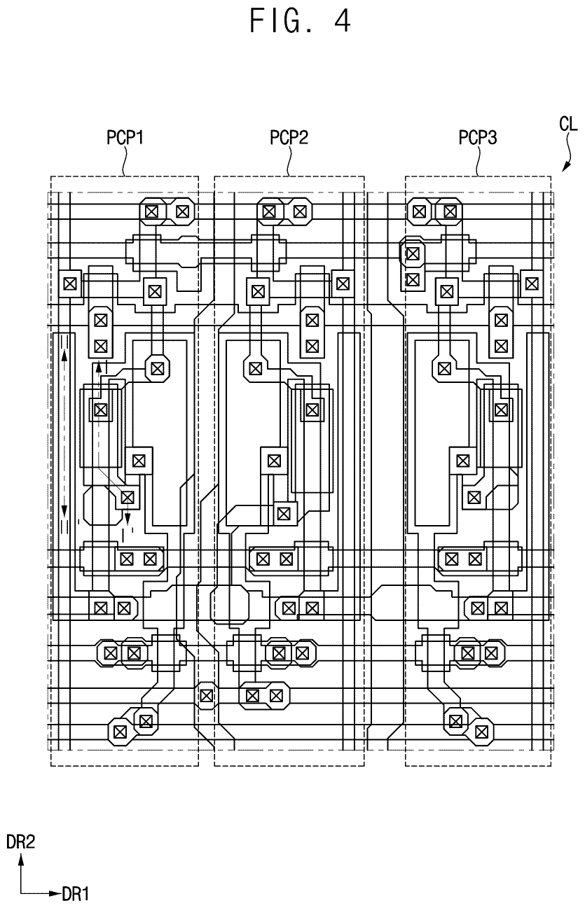

FIG. 4 is a layout view illustrating a circuit layer of FIG. 3.

Referring to FIG. 4, the circuit layer CL may include a first pixel circuit portion PCP1, a second pixel circuit portion PCP2, and a third pixel circuit portion PCP3. In one or more embodiments, the second pixel circuit portion PCP2 may be located adjacent to the first pixel circuit portion PCP1 in the first direction DR1, and the third pixel circuit portion PCP3 may be located adjacent to the second pixel circuit portion PCP2 in the first direction DR1.

The first pixel circuit portion PCP1 may correspond to the first pixel circuit PC1 shown in FIG. 2, and the second pixel circuit portion PCP2 may correspond to the second pixel circuit PC2 shown in FIG. 2. In addition, the third pixel circuit portion PCP3 may correspond to a pixel circuit of the third sub-pixel SPX3 shown in FIG. 1. Hereinafter, the components of each of the first, second, and third pixel circuit portions PCP1, PCP2, and PCP3 will be described in detail.

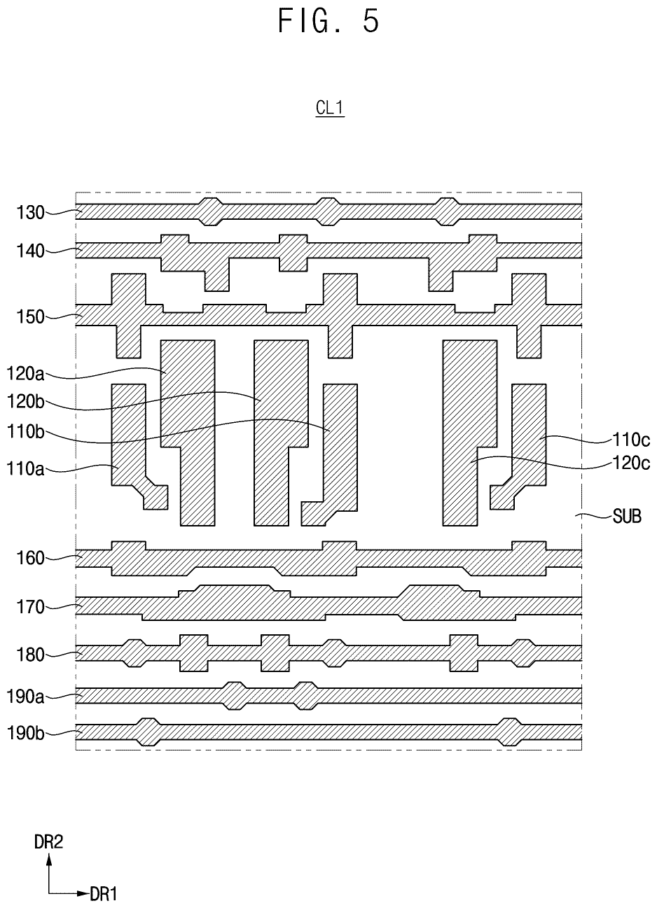

FIGS. 5, 6, 7, 8, 9, and 10 are layout views for explaining components illustrated in the layout view of FIG. 4 by layer.

Referring to FIGS. 4 and 5, the display device DD according to one or more embodiments of the present disclosure may include a first conductive layer CL1 located in the display area DA on the substrate SUB.

The first conductive layer CL1 may include first, second, and third lower conductive patterns 110a, 110b, and 110c, first, second, and third capacitor electrodes 120a, 120b, and 120c, a reference voltage line 130, a first gate line 150, a second gate line 140, a third gate line 180, a light-emitting control line 160, a driving voltage line 170, a first initialization voltage line 190a, and a second initialization voltage line 190b, all of which may include the same material, may be located in the same layer, and/or may be spaced apart from each other.

The first lower conductive pattern 110a may be included in the first pixel circuit portion PCP1, the second lower conductive pattern 110b may be included in the second pixel circuit portion PCP2, and the third lower conductive pattern 110c may be included in the third pixel circuit portion PCP3.

The first capacitor electrode 120a may be included in the first pixel circuit portion PCP1, the second capacitor electrode 120b may be included in the second pixel circuit portion PCP2, and the third capacitor electrode 120c may be included in the third pixel circuit part PCP3.

In one or more embodiments, the second capacitor electrode 120b may have a planar shape that is substantially symmetrical to the first capacitor electrode 120a in the first direction DR1.

The reference voltage line 130 may extend in the first direction DR1. A reference voltage (e.g., the reference voltage VREF of FIG. 2) may be applied to the reference voltage line 130.

The first gate line 150 may extend in the first direction DR1. A first gate signal (e.g., the first gate signal GW of FIG. 2) may be applied to the first gate line 150.

The second gate line 140 may be located between the reference voltage line 130 and the first gate line 150 on a plane. The second gate line 140 may extend in the first direction DR1. A second gate signal (e.g., the second gate signal GR of FIG. 2) may be applied to the second gate line 140.

The third gate line 180 may extend in the first direction DR1. A third gate signal (e.g., the third gate signal GI of FIG. 2) may be applied to the third gate line 180.

The light-emitting control line 160 may extend in the first direction DR1. A light-emitting control signal (e.g., the light-emitting control signal EM of FIG. 2) may be applied to the light-emitting control line 160.

The driving voltage line 170 may be located between the light-emitting control line 160 and the third gate line 180 in the plan view. The driving voltage line 170 may extend in the first direction DR1. A driving voltage (e.g., the driving voltage ELVDD of FIG. 2) may be applied to the driving voltage line 170.

The first initialization voltage line 190a may be located between the third gate line 180 and the second initialization voltage line 190b in the plan view. The first initialization voltage line 190a may extend in the first direction DR1. An initialization voltage (e.g., the initialization voltage VINT of FIG. 2) may be applied to the first initialization voltage line 190a. For example, the initialization voltage applied to the first initialization voltage line 190a may be provided to the second pixel circuit portion PCP2.

The second initialization voltage line 190b may extend in the first direction DR1. An initialization voltage (e.g., the initialization voltage VINT of FIG. 2) may be applied to the second initialization voltage line 190b. For example, the initialization voltage applied to the second initialization voltage line 190b may be provided to the first and third pixel circuit portions PCP1 and PCP3.

The first conductive layer CL1 may include metal, alloy, metal nitride, conductive metal oxide, transparent conductive material, and/or the like. These can be used alone or in combination with each other, according to various embodiments.

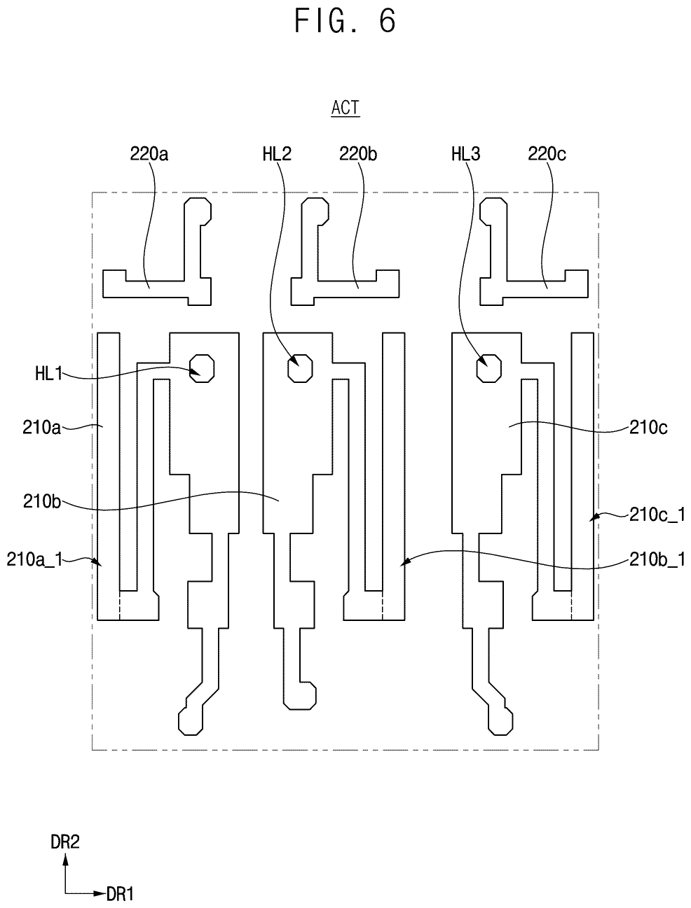

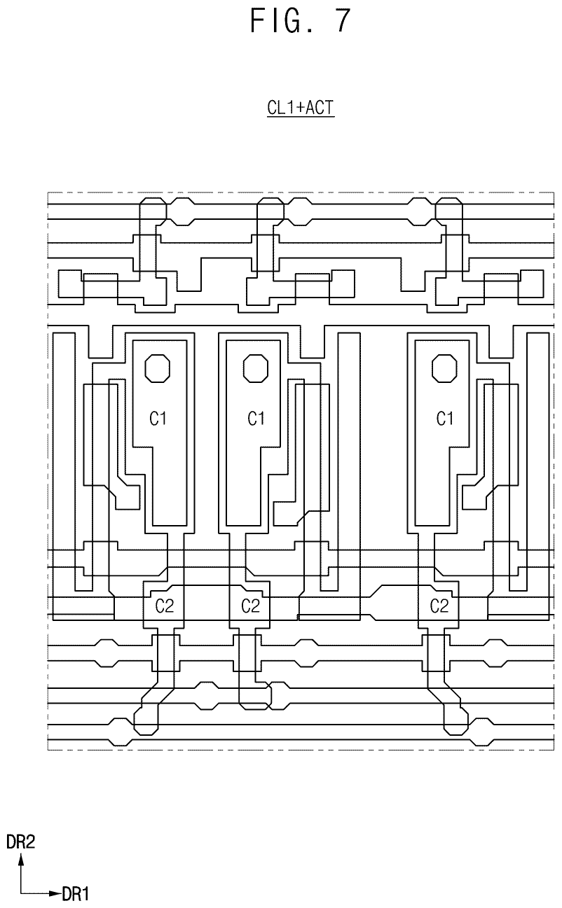

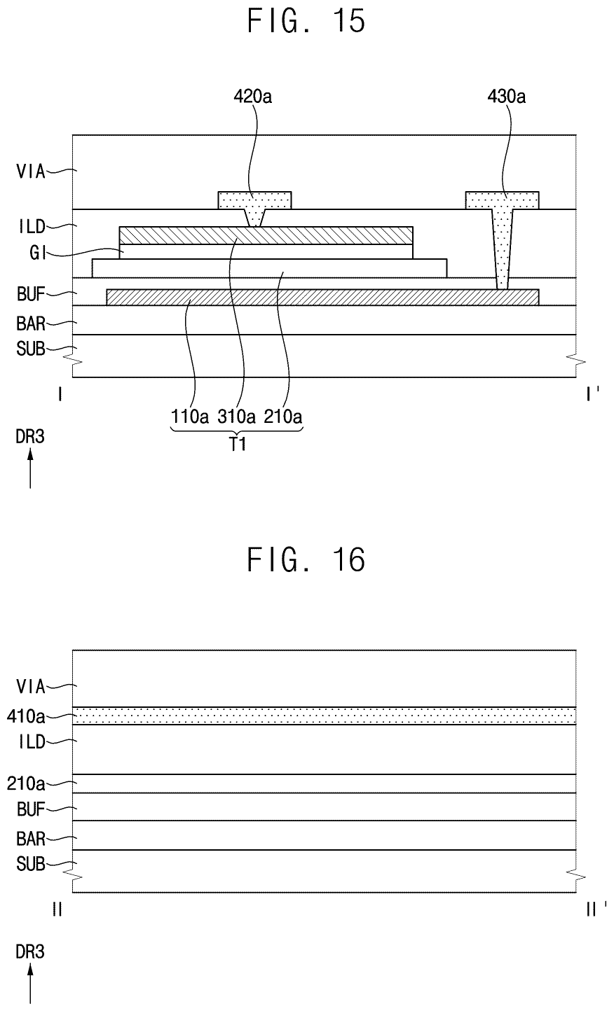

Referring further to FIGS. 6 and 7, the display device DD according to one or more embodiments of the present disclosure may further include an active layer ACT located in the display area DA on the first conductive layer CL1 (e.g., “on,” as used herein, may mean “above”). For example, a buffer layer (e.g., a buffer layer BUF of FIG. 15) may be located on the substrate SUB, and the active layer ACT may be located on the buffer layer.

The active layer ACT may include first, second, third, fourth, fifth, and sixth active patterns 210a, 210b, 210c, 220a, 220b, and 220c, which may include the same material, may be located in the same layer, and/or may be spaced apart from each other.

The first active pattern 210a may be included in the first pixel circuit portion PCP1. The first active pattern 210a may partially overlap the first lower conductive pattern 110a, the first capacitor electrode 120a, the light-emitting control line 160, the driving voltage line 170, the third gate line 180, the first initialization voltage line 190a, and the second initialization voltage line 190b in the plan view.

In one or more embodiments, in the first pixel circuit portion PCP1, a part of the first active pattern 210a overlapping the first capacitor electrode 120a may constitute a first capacitor C1. In addition, in one or more embodiments, in the first pixel circuit portion PCP1, a part of the first active pattern 210a may constitute a second capacitor C2 together with a part of the driving voltage line 170 overlapping therewith.

As shown in FIG. 6, the first active pattern 210a may include a first overlapping part 210a_1 extending in the second direction DR2. In one or more embodiments, the first overlapping part 210a_1 might not overlap the first lower conductive pattern 110a or the first capacitor electrode 120a in the plan view.

The second active pattern 210b may be included in the second pixel circuit portion PCP2. The second active pattern 210b may partially overlap one or more of the second lower conductive pattern 110b, the second capacitor electrode 120b, the light-emitting control line 160, the driving voltage line 170, the third gate line 180, the first initialization voltage line 190a, or the second initialization voltage line 190b in the plan view.

In one or more embodiments, in the second pixel circuit portion PCP2, a part of the second active pattern 210b overlapping the second capacitor electrode 120b may constitute the first capacitor C1. In addition, in one or more embodiments, in the second pixel circuit portion PCP2, a part of the second active pattern 210b may constitute the second capacitor C2 together with a part of the driving voltage line 170.

The second active pattern 210b may include a second overlapping part 210b_1 extending in the second direction DR2. In one or more embodiments, the second overlapping part 210b_1 might not overlap the second lower conductive pattern 110b or the second capacitor electrode 120b in the plan view.

The first capacitor C1 and the second capacitor C2 may respectively correspond to the first capacitor C1 and the second capacitor C2 shown in FIG. 2.

In one or more embodiments, the second active pattern 210b may have a planar shape that is substantially symmetrical to the first active pattern 210a in the first direction DR1.

The third active pattern 210c may be included in the third pixel circuit portion PCP3. The third active pattern 210c may partially overlap the third lower conductive pattern 110c, the third capacitor electrode 120c, the light-emitting control line 160, the driving voltage line 170, the third gate line 180, the first initialization voltage line 190a, and the second initialization voltage line 190b in the plan view.

In one or more embodiments, in the third pixel circuit portion PCP3, a part of the third active pattern 210c overlapping the third capacitor electrode 120c may constitute the first capacitor C1. In addition, in one or more embodiments, in the third pixel circuit portion PCP3, a part of the third active pattern 210c may constitute the second capacitor C2 together with a part of the driving voltage line 170.

The third active pattern 210c may include a third overlapping part 210c_1 extending in the second direction DR2. In one or more embodiments, the third overlapping part 210c_1 might not overlap the third lower conductive pattern 110c or the third capacitor electrode 120c in the plan view.

A first through hole HL1 may be defined in the first active pattern 210a, a second through hole HL2 may be defined in the second active pattern 210b, and a third through hole HL3 may be defined in the third active pattern 210c. The first through hole HL1 may expose at least a part of the first capacitor electrode 120a, the second through hole HL2 may expose at least a part of the second capacitor electrode 120b, and the third through hole HL3 may expose at least a part of the third capacitor electrode 120c.

The fourth active pattern 220a may be included in the first pixel circuit portion PCP1. The fourth active pattern 220a may include a first part extending in the first direction DR1, and a second part extending in the second direction DR2. The first part of the fourth active pattern 220a may partially overlap the first gate line 150 in the plan view. In addition, the second part of the fourth active pattern 220a may partially overlap the reference voltage line 130 and the second gate line 140 in the plan view. For example, the fourth active pattern 220a may have an L-shape rotated 90 degrees counterclockwise in the plan view.

The fifth active pattern 220b may be included in the second pixel circuit portion PCP2. The fifth active pattern 220b may include a first part extending in the first direction DR1, and a second part extending in the second direction DR2. The first part of the fifth active pattern 220b may partially overlap the first gate line 150 in the plan view. In addition, the second part of the fifth active pattern 220b may partially overlap the reference voltage line 130 and the second gate line 140 in the plan view. For example, the fifth active pattern 220b may have an L-shape in the plan view.

In one or more embodiments, the fifth active pattern 220b may have a planar shape that is substantially symmetrical to the fourth active pattern 220a in the first direction DR1.

The sixth active pattern 220c may be included in the third pixel circuit portion PCP3. The sixth active pattern 220c may include a first part extending in the first direction DR1 and a second part extending in the second direction DR2. The first part of the sixth active pattern 220c may partially overlap the first gate line 150 in the plan view. In addition, the second part of the sixth active pattern 220c may partially overlap the reference voltage line 130 and the second gate line 140 in the plan view. For example, the sixth active pattern 220c may have substantially the same planar shape as the fifth active pattern 220b.

The active layer ACT may include a semiconductor. In one or more embodiments, the active layer ACT may include a metal oxide semiconductor. The metal oxide semiconductor may include a two-component compound (ABₓ), a three-component compound (ABₓC_{y}), a four-component compound (ABₓC_{y}D_{z}), and/or the like containing indium (In), zinc (Zn), gallium (Ga), tin (Sn), titanium (Ti), aluminum (Al), hafnium (Hf), zirconium (Zr), magnesium (Mg), and/or the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and/or the like. The above can be used alone or in combination with each other.

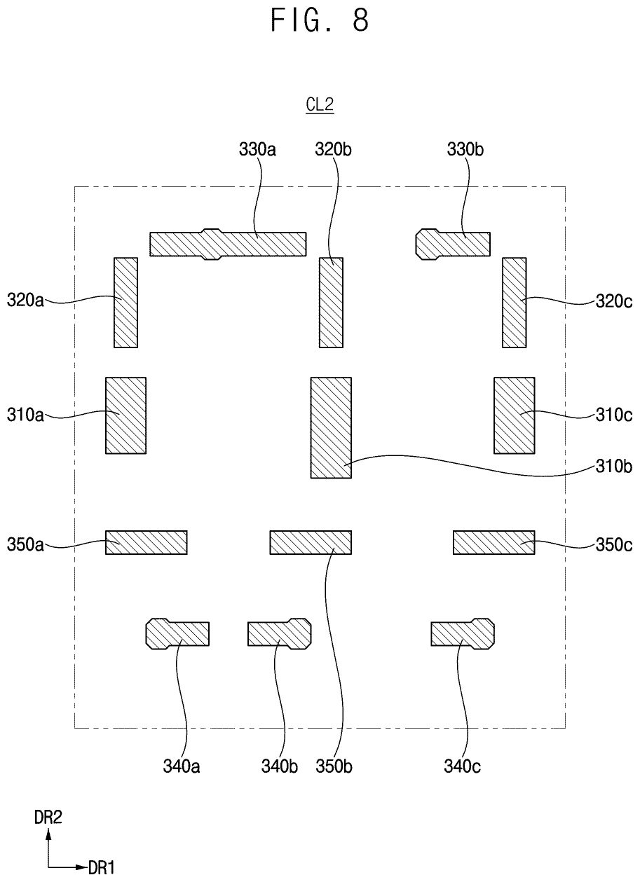

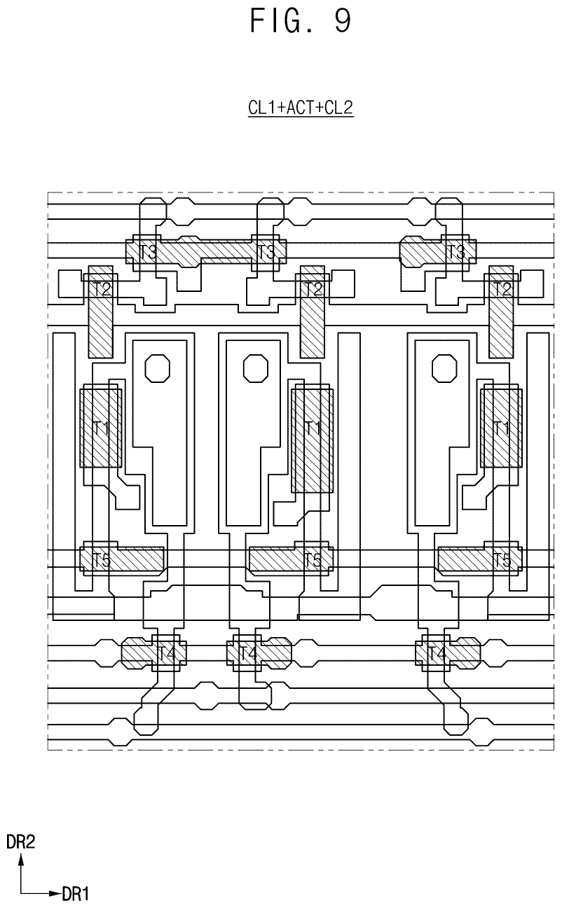

Referring further to FIGS. 8 and 9, the display device DD according to one or more embodiments of the present disclosure may further include a second conductive layer CL2 located on the active layer ACT. For example, a gate-insulating layer (e.g., the gate-insulating layer GI of FIG. 15) may be located on the active layer ACT, and the second conductive layer CL2 may be located on/above the gate-insulating layer.

The second conductive layer CL2 may include first-first, first-second, and first-third gate electrodes 310a, 310b, and 310c, second-first, second-second, and second-third gate electrodes 320a, 320b, and 320c, third-first and third-second gate electrodes 330a and 330b, fourth-first, fourth-second, and fourth-third gate electrodes 340a, 340b, and 340c, and fifth-first, fifth-second, and fifth-third gate electrodes 350a, 350b, and 350c, which may include the same material, may be located in the same layer, and/or may be spaced apart from each other.

The first-first gate electrode 310a may partially overlap the first lower conductive pattern 110a and the first active pattern 210a in the plan view. Accordingly, in the first pixel circuit portion PCP1, the first-first gate electrode 310a may constitute a first transistor T1 together with the first lower conductive pattern 110a and a part of the first active pattern 210a (see FIG. 15).

The first-second gate electrode 310b may partially overlap the second lower conductive pattern 110b and the second active pattern 210b in the plan view. Accordingly, in the second pixel circuit portion PCP2, the first-second gate electrode 310b may constitute the first transistor T1 together with the second lower conductive pattern 110b and a part of the second active pattern 210b.

The first-third gate electrodes 310c may partially overlap the third lower conductive pattern 110c and the third active pattern 210c in the plan view. Accordingly, in the third pixel circuit portion PCP3, the first-third gate electrode 310c may constitute the first transistor T1 together with the third lower conductive pattern 110c and a part of the third active pattern 210c.

The second-first gate electrode 320a may partially overlap the first gate line 150 and the fourth active pattern 220a in the plan view. Accordingly, in the first pixel circuit portion PCP1, the second-first gate electrode 320a may constitute a second transistor T2 together with a part of the fourth active pattern 220a.

The second-second gate electrode 320b may partially overlap the first gate line 150 and the fifth active pattern 220b in the plan view. Accordingly, in the second pixel circuit portion PCP2, the second-second gate electrode 320b may constitute the second transistor T2 together with a part of the fifth active pattern 220b.

In one or more embodiments, the second-second gate electrode 320b may have a planar shape that is substantially symmetrical to the second-first gate electrode 320a in the first direction DR1.

The second-third gate electrode 320c may partially overlap the first gate line 150 and the sixth active pattern 220c in the plan view. Accordingly, in the third pixel circuit portion PCP3, the second-third gate electrode 320c may constitute the second transistor T2 together with a part of the sixth active pattern 220c.

The third-first gate electrode 330a may partially overlap the second gate line 140, the fourth active pattern 220a, and the fifth active pattern 220b in the plan view. Accordingly, in the first pixel circuit portion PCP1, a part of the third-first gate electrode 330a overlapping the fourth active pattern 220a may constitute a third transistor T3 together with another part of the fourth active pattern 220a. In addition, in the second pixel circuit portion PCP2, another part of the third-first gate electrode 330a overlapping the fifth active pattern 220b may constitute the third transistor T3 together with another part of the fifth active pattern 220b.

The third-second gate electrode 330b may partially overlap the second gate line 140 and the sixth active pattern 220c in the plan view. Accordingly, in the third pixel circuit portion PCP3, the third-second gate electrode 330b may constitute the third transistor T3 together with another part of the sixth active pattern 220c.

The fourth-first gate electrode 340a may partially overlap the third gate line 180 and the first active pattern 210a in the plan view. Accordingly, in the first pixel circuit portion PCP1, the fourth-first gate electrode 340a may constitute a fourth transistor T4 together with a part of the first active pattern 210a.

The fourth-second gate electrode 340b may partially overlap the third gate line 180 and the second active pattern 210b in the plan view. Accordingly, in the second pixel circuit portion PCP2, the fourth-second gate electrode 340b may constitute the fourth transistor T4 together with a part of the second active pattern 210b.

In one or more embodiments, the fourth-second gate electrode 340b may have a planar shape that is substantially symmetrical to the fourth-first gate electrode 340a in the first direction DR1.

The fourth-third gate electrode 340c may partially overlap the third gate line 180 and the third active pattern 210c in the plan view. Accordingly, in the third pixel circuit portion PCP3, the fourth-third gate electrode 340c may constitute the fourth transistor T4 together with a part of the third active pattern 210c.

The fifth-first gate electrode 350a may partially overlap the light-emitting control line 160 and the first active pattern 210a in the plan view. Accordingly, in the first pixel circuit portion PCP1, the fifth-first gate electrode 350a may constitute the fifth transistor T5 together with a part of the first active pattern 210a.

The fifth-second gate electrode 350b may partially overlap the light-emitting control line 160 and the second active pattern 210b in the plan view. Accordingly, in the second pixel circuit portion PCP2, the fifth-second gate electrode 350b may constitute the fifth transistor T5 together with a part of the second active pattern 210b.

In one or more embodiments, the fifth-second gate electrode 350b may have a planar shape that is substantially symmetrical to the fifth-first gate electrode 350a in the first direction DR1.

The fifth-third gate electrode 350c may partially overlap the light-emitting control line 160 and the third active pattern 210c in the plan view. Accordingly, in the third pixel circuit portion PCP3, the fifth-third gate electrode 350c may constitute the fifth transistor T5 together with a part of the third active pattern 210c.

The second conductive layer CL2 may include metal, alloy, metal nitride, conductive metal oxide, transparent conductive material, and/or the like. These can be used alone or in combination with each other.

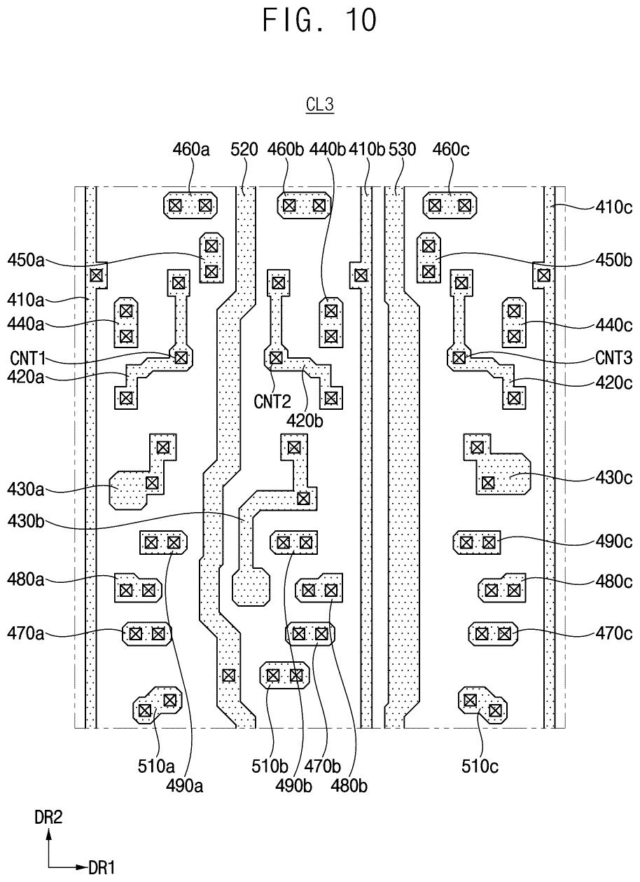

Referring further to FIG. 10, the display device DD according to one or more embodiments of the present disclosure may further include a third conductive layer CL3 located on/above the second conductive layer CL2. For example, an interlayer insulating layer (e.g., an interlayer insulating layer ILD of FIG. 15) may be located on the second conductive layer CL2, and the third conductive layer CL3 may be located on the interlayer insulating layer.

The third conductive layer CL3 may include first, second, and third data lines 410a, 410b, and 410c, first, second, and third connection patterns 420a, 420b, and 420c, first, second, and third anode connection patterns 430a, 430b, and 430c, first-first, first-second, and first-third gate connection patterns 440a, 440b, and 440c, second-first and second-second gate connection patterns 450a and 450b, first, second, and third reference voltage connection patterns 460a, 460b, and 460c, third-first, third-second, and third-third gate connection patterns 470a, 470b, and 470c, first, second, and third driving voltage connection patterns 480a, 480b, and 480c, first, second, and third light-emitting control connection patterns 490a, 490b, and 490c, first, second, and third initialization voltage connection patterns 510a, 510b, and 510c, a first voltage line 520, and a second voltage line 530, all of which may include the same material, may be located in the same layer, and/or may be spaced apart from each other.

Each of the first, second, and third data lines 410a, 410b, and 410c may extend in the second direction DR2. The first, second, and third data lines 410a, 410b, and 410c may be connected to the fourth, fifth, and sixth active patterns 220a, 220b, and 220c through respective contact holes,

A data voltage (e.g., the data voltage DATA of FIG. 2) may be applied to the first, second, and third data lines 410a, 410b, and 410c. Accordingly, the data voltage may be transmitted to the fourth, fifth, and sixth active patterns 220a, 220b, and 220c through the first, second, and third data lines 410a, 410b, and 410c, respectively.

In one or more embodiments, the first data line 410a may overlap the first overlapping part 210a_1 extending in the second direction DR2 of the first active pattern 210a in the plan view. Likewise, each of the second and third data lines 410b and 410c may respectively overlap the second and third overlapping parts 210b_1 and 210c_1 extending in the second direction DR2 each of the second and third active patterns 210b and 210c in the plan view. Accordingly, the formation of a parasitic capacitor between the first, second, and third data lines 410a, 410b, and 410c, and peripheral lines can be minimized or reduced.

The first connection pattern 420a may connect the first-first gate electrode 310a and the fourth active pattern 220a through one or more contact holes (see FIG. 15). In addition, the first connection pattern 420a may be connected to the first capacitor electrode 120a through a first contact hole CNT1 overlapping the first through hole HL1. Accordingly, the data voltage may be transmitted to the first-first gate electrode 310a through the first connection pattern 420a.

The second connection pattern 420b may connect the second active pattern 210b and the fifth active pattern 220b through one or more contact holes. In addition, the second connection pattern 420b may be connected to the second capacitor electrode 120b through a second contact hole CNT2 overlapping the second through hole HL2. Accordingly, the data voltage may be transmitted to the first-second gate electrode 310b through the second connection pattern 420b.

In one or more embodiments, the second connection pattern 420b may have a planar shape that is symmetrical to the first connection pattern 420a in the first direction DR1.

The third connection pattern 420c may connect the third active pattern 210c and the sixth active pattern 220c through one or more contact holes. In addition, the third connection pattern 420c may be connected to the third capacitor electrode 120c through a third contact hole CNT3 overlapping the third through hole HL3. Accordingly, the data voltage may be transmitted to the first-third gate electrode 310c through the third connection pattern 420c.

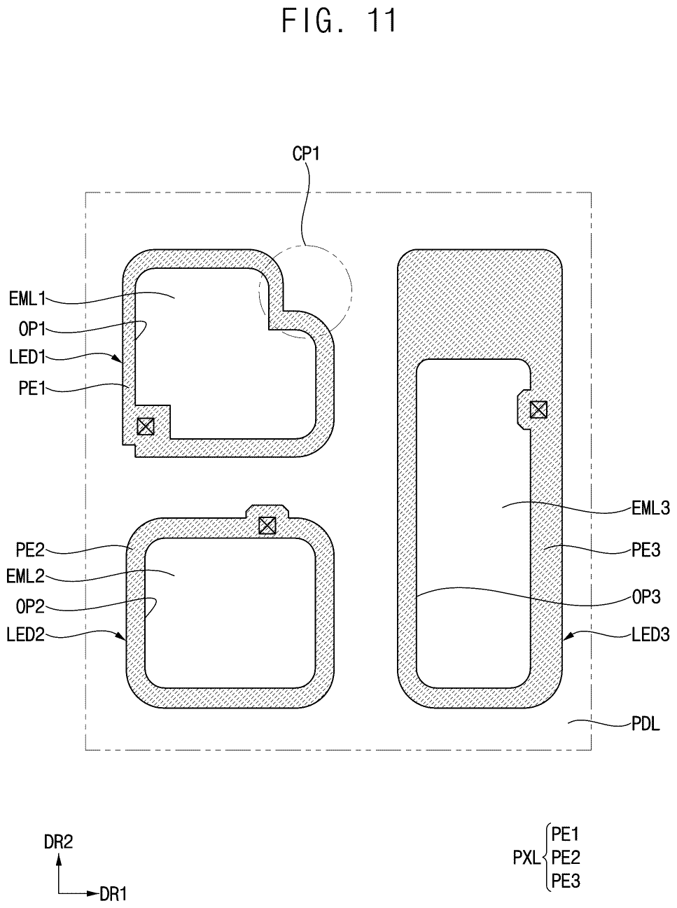

The first anode connection pattern 430a may connect the first active pattern 210a and the first lower conductive pattern 110a through one or more contact holes (see FIG. 15). In addition, the first anode connection pattern 430a may be connected to a first pixel electrode (e.g., the first pixel electrode PE1 of FIG. 11) through a contact hole. Accordingly, the first anode connection pattern 430a may connect the first active pattern 210a, the first lower conductive pattern 110a, and a first light-emitting element (e.g., the first light-emitting element LED1 of FIG. 11).

The second anode connection pattern 430b may connect the second active pattern 210b and the second lower conductive pattern 110b through one or more contact holes. In addition, the second anode connection pattern 430b may be connected to a second pixel electrode (e.g., the second pixel electrode PE2 of FIG. 11) through a contact hole. Accordingly, the second anode connection pattern 430b may connect the second active pattern 210b, the second lower conductive pattern 110b, and a second light-emitting element (e.g., the second light-emitting element LED2 of FIG. 11).

The third anode connection pattern 430c may connect the third active pattern 210c and the third lower conductive pattern 110c through one or more contact holes. In addition, the third anode connection pattern 430c may be connected to a third pixel electrode (e.g., the third pixel electrode PE3 of FIG. 11) through a contact hole. Accordingly, the third anode connection pattern 430c may connect the third active pattern 210c, the third lower conductive pattern 110c, and a third light-emitting element (e.g., the third light-emitting element LED3 of FIG. 11).

The first-first gate connection pattern 440a may connect the first gate line 150 and the second-first gate electrode 320a through one or more contact holes. Accordingly, the first gate signal applied to the first gate line 150 may be transmitted to the second-first gate electrode 320a.

The first-second gate connection pattern 440b may connect the first gate line 150 and the second-second gate electrode 320b through one or more contact holes. Accordingly, the first gate signal applied to the first gate line 150 may be transmitted to the second-second gate electrode 320b.

In one or more embodiments, the first-second gate connection pattern 440b may have a planar shape that is substantially symmetrical to the first-first gate connection pattern 440a in the first direction DR1.

The first-third gate connection pattern 440c may connect the first gate line 150 and the second-third gate electrode 320c through one or more contact holes. Accordingly, the first gate signal applied to the first gate line 150 may be transmitted to the second-third gate electrode 320c.

The second-first gate connection pattern 450a may connect the second gate line 140 and the third-first gate electrode 330a through one or more contact holes. Accordingly, the second gate signal applied to the second gate line 140 may be transmitted to the third-first gate electrode 330a.

The second-second gate connection pattern 450b may connect the second gate line 140 and the third-second gate electrode 330b through one or more contact holes. Accordingly, the second gate signal applied to the second gate line 140 may be transmitted to the third-second gate electrode 330b.

The first reference voltage connection pattern 460a may connect the reference voltage line 130 and the fourth active pattern 220a through one or more contact holes. Accordingly, the reference voltage applied to the reference voltage line 130 may be transmitted to the fourth active pattern 220a.

The second reference voltage connection pattern 460b may connect the reference voltage line 130 and the fifth active pattern 220b through one or more contact holes. Accordingly, the reference voltage applied to the reference voltage line 130 may be transmitted to the fifth active pattern 220b.

The third reference voltage connection pattern 460c may connect the reference voltage line 130 and the sixth active pattern 220c through one or more contact holes. Accordingly, the reference voltage applied to the reference voltage line 130 may be transmitted to the sixth active pattern 220c.

The third-first gate connection pattern 470a may connect the third gate line 180 and the fourth-first gate electrode 340a through one or more contact holes. Accordingly, the third gate signal applied to the third gate line 180 may be transmitted to the fourth-first gate electrode 340a.

The third-second gate connection pattern 470b may connect the third gate line 180 and the fourth-second gate electrode 340b through one or more contact holes. Accordingly, the third gate signal applied to the third gate line 180 may be transmitted to the fourth-second gate electrode 340b.

In one or more embodiments, the third-second gate connection pattern 470b may have a planar shape that is substantially symmetrical to the third-first gate connection pattern 470a in the first direction DR1.

The third-third gate connection pattern 470c may connect the third gate line 180 and the fourth-third gate electrode 340c through one or more contact holes. Accordingly, the third gate signal applied to the third gate line 180 may be transmitted to the fourth-third gate electrode 340c.

The first driving voltage connection pattern 480a may connect the driving voltage line 170 and the first active pattern 210a through one or more contact holes. Accordingly, the driving voltage applied to the driving voltage line 170 may be transmitted to the first active pattern 210a.

The second driving voltage connection pattern 480b may connect the driving voltage line 170 and the second active pattern 210b through one or more contact holes. Accordingly, the driving voltage applied to the driving voltage line 170 may be transmitted to the second active pattern 210b.

In one or more embodiments, the second driving voltage connection pattern 480b may have a planar shape that is substantially symmetrical to the first driving voltage connection pattern 480a in the first direction DR1.

The third driving voltage connection pattern 480c may connect the driving voltage line 170 and the third active pattern 210c through one or more contact holes. Accordingly, the driving voltage applied to the driving voltage line 170 may be transmitted to the third active pattern 210c.

The first emission control connection pattern 490a may connect the light-emitting control line 160 and the fifth-first gate electrode 350a through one or more contact holes. Accordingly, the light-emitting control signal applied to the light-emitting control line 160 may be transmitted to the fifth-first gate electrode 350a.

The second emission control connection pattern 490b may connect the light-emitting control line 160 and the fifth-second gate electrode 350b through one or more contact holes. Accordingly, the light-emitting control signal applied to the light-emitting control line 160 may be transmitted to the fifth-second gate electrode 350b.

In one or more embodiments, the second emission control connection pattern 490b may have a planar shape that is substantially symmetrical to the first emission control connection pattern 490a in the first direction DR1.

The third emission control connection pattern 490c may connect the light-emitting control line 160 and the fifth-third gate electrode 350c through one or more contact holes. Accordingly, the light-emitting control signal applied to the light-emitting control line 160 may be transmitted to the fifth-third gate electrode 350c.

The first initialization voltage connection pattern 510a may connect the second initialization voltage line 190b and the first active pattern 210a through one or more contact holes. Accordingly, the second initialization voltage applied to the second initialization voltage line 190b may be transmitted to the first active pattern 210a.

The second initialization voltage connection pattern 510b may connect the first initialization voltage line 190a and the second active pattern 210b through one or more contact holes. Accordingly, the first initialization voltage applied to the first initialization voltage line 190a may be transmitted to the second active pattern 210b.

The third initialization voltage connection pattern 510c may connect the second initialization voltage line 190b and the third active pattern 210c through one or more contact holes. Accordingly, the second initialization voltage applied to the second initialization voltage line 190b may be transmitted to the third active pattern 210c.

The first voltage line 520 may extend in the second direction DR2. For example, the first voltage line 520 may be connected to the first initialization voltage line 190a through a contact hole. In this case, the first initialization voltage may be applied to the first voltage line 520. Alternatively, when the first voltage line 520 is connected to the reference voltage line 130, the reference voltage may be applied to the first voltage line 520.

The second voltage line 530 may extend in the second direction DR2. For example, a common voltage (e.g., the common voltage ELVSS of FIG. 2) may be applied to the second voltage line 530. Alternatively, the driving voltage may be applied to the second voltage line 530.

In summary, the first conductive layer CL1, the active layer ACT, the second conductive layer CL2, and the third conductive layer CL3 may collectively form the first, second, and third pixel circuit portions PCP1, PCP2, and PCP3.

FIG. 11 is a layout view illustrating first, second, and third light-emitting elements of a display device according to one or more embodiments of the present disclosure.

Referring to FIG. 11, the first light-emitting element LED1 may include the first pixel electrode PE1, a first light-emitting layer EML1, and a common electrode (e.g., the common electrode CTE of FIG. 3). The light-emitting element LED2 may include the second pixel electrode PE2, a second light-emitting layer EML2, and the common electrode. The third light-emitting element LED3 may include the third pixel electrode PE3, a third light-emitting layer EML3, and the common electrode. The first, second, and third pixel electrodes PE1, PE2, and PE3 may constitute a pixel electrode layer PXL.

The first light-emitting element LED1 may be located adjacent to the second light-emitting element LED2 in the second direction DR2, and the third light-emitting element LED3 may be located adjacent to the first and second light-emitting elements LED1 and LED2 in the first direction DR1. That is, the first pixel electrode PE1 may be located adjacent to the second pixel electrode PE2 in the second direction DR2, and the third pixel electrode PE3 may be located adjacent to the first and second pixel electrodes PE1 and PE2 in the first direction DR1.

A first opening OP1 exposing at least a part of an upper surface of the first pixel electrode PE1, a second opening OP2 exposing at least a part of an upper surface of the second pixel electrode PE2, and a third opening OP3 exposing at least a part of an upper surface of the third pixel electrode PE3 may be defined in the pixel-defining layer PDL.

The first light-emitting layer EML1 may be located in the first opening OP1, the second light-emitting layer EML2 may be located in the second opening OP2, and the third light-emitting layer EML3 may be located in the third opening OP3. In one or more embodiments, the first light-emitting layer EML1 may include a light-emitting material that emits red light, the second light-emitting layer EML2 may include a light-emitting material that emits green light, and the third light-emitting layer EML3 may include a light-emitting material that emits blue light. However, embodiments of the present disclosure are not limited to this, and the first light-emitting layer EML1 may include a light-emitting material that emits red light, green light, or blue light. In this case, each of the second light emitting layer EML2 and the third light emitting layer EML3 may include a light-emitting material that emits light of a color that is different from that of a light-emitting material of the first light emitting layer EML1.

In one or more other embodiments, the first, second, and third light-emitting layers EML1, EML2, and EML3 may continuously extend into the first, second, and third openings OP1, OP2, and OP3 on the pixel-defining layer PDL to form an organic light-emitting layer. That is, each of the first, second, and third light emitting elements LED1, LED2, and LED3 may commonly include the organic light-emitting layer.

For example, the organic light-emitting layer may include a first blue light-emitting layer, a yellow light-emitting layer, a red light-emitting layer (or a green light-emitting layer), and a second blue light-emitting layer, which are sequentially stacked. In this case, the stacking order of the yellow light-emitting layer and the red light-emitting layer may be changed.

Alternatively, the organic light-emitting layer may include a first blue light-emitting layer, a red light-emitting layer, a yellow light-emitting layer, a green light-emitting layer, and a second blue light-emitting layer sequentially stacked. In this case, the stacking order of the red light-emitting layer and the green light-emitting layer may be changed.

When the first, second, and third light-emitting layers EML1, EML2, and EML3 constitute the organic light-emitting layer, the display device DD may further include a color filter layer that selectively transmits light of a corresponding color. Due to the color filter layer, a red pixel area in which a first sub-pixel (e.g., the first sub-pixel SPX1 of FIG. 1) is located to emit red light, a green pixel area in which a second sub-pixel (e.g., the second sub-pixel SPX2 of FIG. 1) is located to emit green light, and a blue pixel area in which a third sub-pixel (e.g., the third sub-pixel SPX3 of FIG. 1) is located to emit blue light may be defined.

In one or more embodiments, the first pixel electrode PE1 may have a quadrilateral shape (e.g., a quadrilateral with rounded corners except for a first corner part CP1) including the first corner part CP1 recessed in an L-shape in the plan view. In this case, the first opening OP1 may also have a shape including a corner part recessed in an L-shape in the plan view.

For example, each of the second and third pixel electrodes PE2 and PE3 may have a quadrilateral (e.g., a quadrilateral with rounded corners) shape in the plan view.

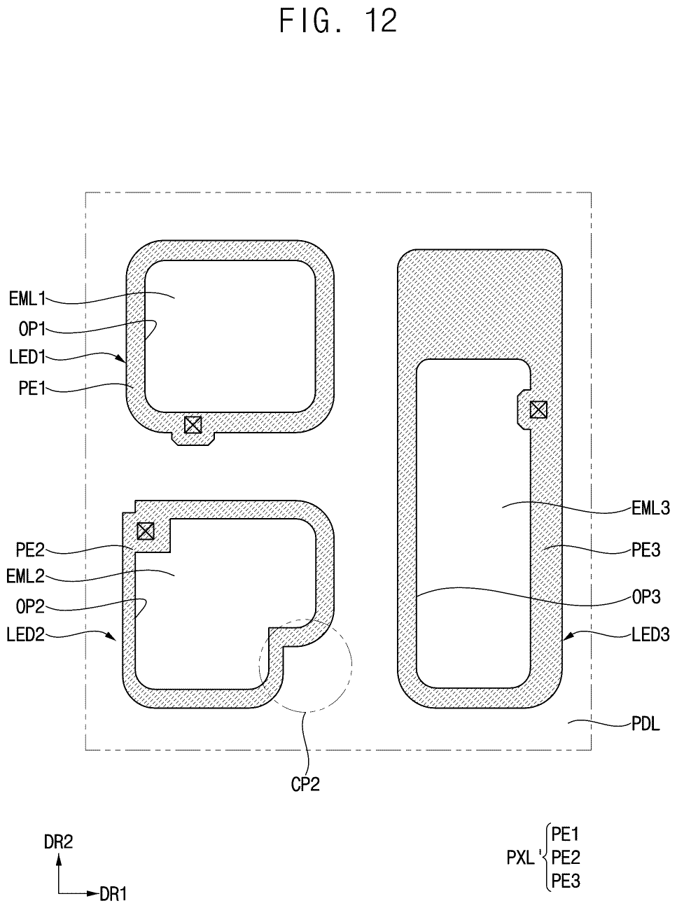

FIG. 12 is a layout view illustrating first, second, and third light-emitting elements of a display device according to one or more other embodiments of the present disclosure. Hereinafter, descriptions overlapping with the first, second, and third light-emitting elements LED1, LED2, and LED2 described with reference to FIG. 11 will be omitted or simplified.

Referring to FIGS. 4 and 12, the first light-emitting element LED1 may include the first pixel electrode PE1, the first light-emitting layer EML1, and the common electrode (e.g., the common electrode CTE of FIG. 3), the light-emitting element LED2 may include the second pixel electrode PE2, the second light-emitting layer EML2, and the common electrode, and the third light-emitting element LED3 may include the third pixel electrode PE3, the third light-emitting layer EML3, and the common electrode. The first, second, and third pixel electrodes PE1, PE2, and PE3 may constitute a pixel electrode layer PXL′.

In one or more embodiments, the second pixel electrode PE2 may have a quadrilateral (e.g., a quadrilateral with rounded corners except for a second corner part CP2) shape including the second corner part CP2 recessed in an L-shape (e.g., an inverted or rotated L-shape) in the plan view. In this case, the second opening OP2 may also have a shape including a corner part recessed in an L-shape in the plan view.

For example, when the positions of the first pixel circuit portion PCP1 and the second pixel circuit portion PCP2 are changed and the structures of the first, second, and third pixel circuit portions PCP1, PCP2, and PCP3 are changed, the second pixel electrode PE2 may overlap a driving gate node (e.g., the first connection pattern 420a of FIG. 10) connected to a gate electrode of a driving transistor (e.g., the first transistor T1 of FIG. 9) included in the first pixel circuit portion PCP1 in the plan view. In this case, when the second pixel electrode PE2 has the shape shown in FIG. 12, the second pixel electrode PE2 might not overlap the driving gate node connected to the gate electrode of the driving transistor included in the first pixel circuit portion PCP1.

For example, each of the first and third pixel electrodes PE1 and PE3 may have a quadrilateral (e.g., a quadrilateral with rounded corners) shape in the plan view.

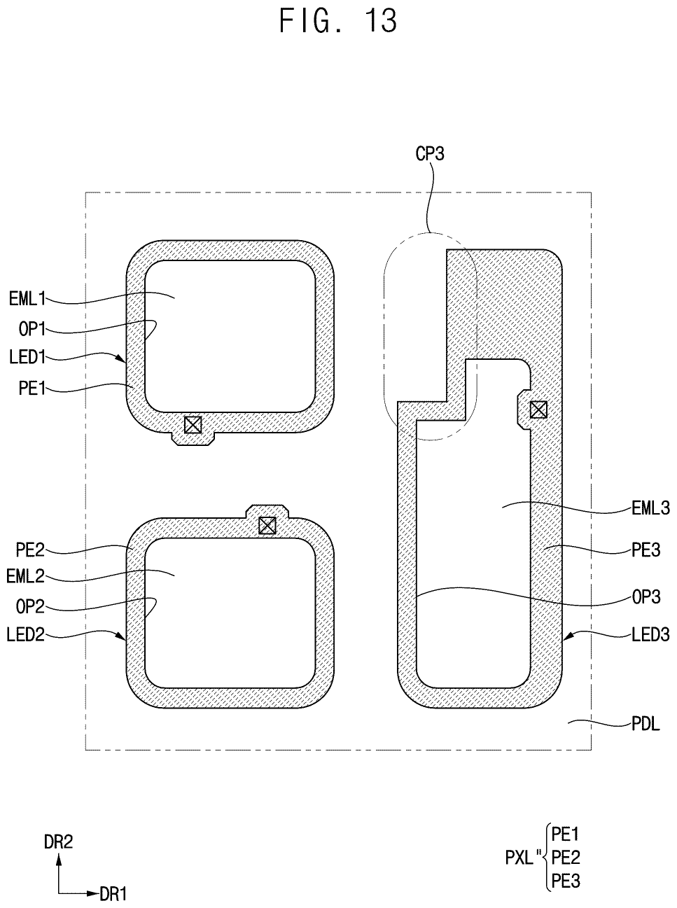

FIG. 13 is a layout view illustrating first, second, and third light-emitting elements of a display device according to still one or more other embodiments of the present disclosure. Hereinafter, descriptions overlapping with the first, second, and third light-emitting elements LED1, LED2, and LED2 described with reference to FIG. 11 will be omitted or simplified.

Referring to FIGS. 4 and 13, the first light-emitting element LED1 may include the first pixel electrode PE1, the first light-emitting layer EML1, and the common electrode (e.g., the common electrode CTE of FIG. 3), the light-emitting element LED2 may include the second pixel electrode PE2, the second light-emitting layer EML2, and the common electrode, and the third light-emitting element LED3 may include the third pixel electrode PE3, the third light-emitting layer EML3, and the common electrode. The first, second, and third pixel electrodes PE1, PE2, and PE3 may constitute a pixel electrode layer PXL″.

In one or more embodiments, the third pixel electrode PE3 may have a quadrilateral (e.g., a quadrilateral with rounded corners except for a third corner part CP3) shape including the third corner part CP3 recessed in an L-shape (e.g., a mirrored or rotated L-shape) in the plan view. In this case, the third opening OP3 may also have a shape including a corner part recessed in an L-shape in the plan view.

For example, when the structures of the first, second, and third pixel circuit portions PCP1, PCP2, and PCP3 are changed, the third pixel electrode PE3 may overlap a driving gate node (e.g., the second connection pattern 420b of FIG. 10) connected to a gate electrode of a driving transistor (e.g., the first transistor T1 of FIG. 9) included in the second pixel circuit portion PCP2 in the plan view. In this case, when the third pixel electrode PE3 has the shape shown in FIG. 12, the third pixel electrode PE3 might not overlap the driving gate node connected to the gate electrode of the driving transistor included in the second pixel circuit portion PCP2.

For example, each of the first and second pixel electrodes PE1 and PE2 may have a quadrilateral (e.g., a quadrilateral with rounded corners) shape in the plan view.

However, unlike shown in FIGS. 11, 12, and 13, each of two of the first, second, and third pixel electrodes PE1, PE2, and PE3 have a quadrilateral shape including a corner part recessed in an L-shape in the plan view.

FIG. 14 is a layout view illustrating first, second, and third light-emitting elements located on first, second, and third pixel circuits of FIG. 4. For example, the first, second, and third light emitting elements LED1, LED2, and LED3 shown in FIG. 14 may correspond to the first, second, and third light emitting elements LED1, LED2, and LED3 shown in FIG. 11, respectively.

Referring to FIGS. 10, 11, and 14, the first sub-pixel SPX1 may include the first pixel circuit portion PCP1, and the first light-emitting element LED1 located on the first pixel circuit portion PCP1 and electrically connected to the first pixel circuit portion PCP1. For example, the first pixel electrode PE1 of the first light-emitting element LED1 may be connected to the first anode connection pattern 430a through a contact hole.

The second sub-pixel SPX2 may include the second pixel circuit portion PCP2, and the second light-emitting element LED2 located on the second pixel circuit portion PCP2 and electrically connected to the second pixel circuit portion PCP2. For example, the second pixel electrode PE2 of the second light-emitting element LED2 may be connected to the second anode connection pattern 430b through a contact hole.

The third sub-pixel SPX3 may include the third pixel circuit portion PCP3, and the third light-emitting element LED3 located on the third pixel circuit portion PCP3 and electrically connected to the third pixel circuit portion PCP3. For example, the third pixel electrode PE3 of the third light-emitting element LED3 may be connected to the third anode connection pattern 430c through a contact hole.

In one or more embodiments, the first pixel electrode PE1 may partially overlap the second pixel circuit portion PCP2 in the plan view, and the second pixel electrode PE2 may partially overlap the first pixel circuit portion PCP1 in the plan view. That is, the first light-emitting element LED1 may partially overlap the second pixel circuit portion PCP2 in the plan view, and the second light-emitting element LED2 may partially overlap the first pixel circuit portion PCP1 in the plan view.

In one or more embodiments, when the first pixel electrode PE1 has a quadrilateral shape including the first corner portion CP1 recessed in an L-shape, the first pixel electrode PE1 might not overlap the second connection pattern 420b in the plan view. In this case, the first pixel electrode PE1 might not overlap the second contact hole CNT2 in the plan view. Accordingly, the formation of a parasitic capacitor between the first pixel electrode PE1 of the first light-emitting element LED1 included in the first sub-pixel SPX1, and the second connection pattern 420b connected to the first-second gate electrode 310b of the first transistor T1 included in the second sub-pixel SPX2 adjacent to the first sub-pixel SPX1, can be minimized or reduced.

FIG. 15 is a cross-sectional view taken along the line I-I′ of FIG. 4.

Referring to FIG. 15, a barrier layer BAR may be located on the substrate SUB. For example, the barrier layer BAR may include an inorganic material, such as silicon oxide, silicon nitride, silicon oxynitride, amorphous silicon, and/or the like. These can be used alone or in combination with each other.

The first lower conductive pattern 110a may be located on the barrier layer BAR. The buffer layer BUF may be located on the barrier layer BAR. The buffer layer BUF may cover the first lower conductive pattern 110a.

The first active pattern 210a may be located on the buffer layer BUF. The first active pattern 210a may partially overlap the first lower conductive pattern 110a in the plan view. The gate-insulating layer GI may be located on the first active pattern 210a. The gate-insulating layer GI may be patterned to overlap only a part of the first active pattern 210a. For example, the gate-insulating layer GI may include an inorganic material, such as silicon oxide, silicon nitride, silicon oxynitride, and/or the like. These can be used alone or in combination with each other.

The first-first gate electrode 310a may be located on the gate-insulating layer GI. The first-first gate electrode 310a may partially overlap the first active pattern 210a in the plan view. Accordingly, the first lower conductive pattern 110a, a part of the first active pattern 210a, and the first-first gate electrode 310a may constitute the first transistor T1.

The interlayer insulating layer ILD may be located on the buffer layer BUF. The interlayer insulating layer ILD may cover the first active pattern 210a, the gate-insulating layer GI, and the first-first gate electrode 310a. For example, the interlayer dielectric layer ILD may include an inorganic material, such as silicon oxide, silicon nitride, silicon oxynitride, and/or the like. These can be used alone or in combination with each other.

The first connection pattern 420a and the first anode connection pattern 430a may be located on the interlayer insulating layer ILD. The first connection pattern 420a may be connected to the first-first gate electrode 310a through a contact hole penetrating a part of the interlayer insulating layer ILD. The first anode connection pattern 430a may be connected to the first lower conductive pattern 110a through a contact hole penetrating the buffer layer BUF and a part of the interlayer insulating layer ILD.

The via insulating layer VIA may be located on the interlayer insulating layer ILD. The via insulation layer VIA may sufficiently cover the first connection pattern 420a and the first anode connection pattern 430a. The via insulating layer VIA may have a substantially flat upper surface. For example, the via insulating layer VIA may include an organic material, such as phenolic resin, polyacrylates resin, polyimides resin, polyamides resin, siloxane resin, epoxy resin, and/or the like. These can be used alone or in combination with each other.

FIG. 16 is a cross-sectional view taken along the line II-II′ of FIG. 4. Hereinafter, descriptions overlapping with those described with reference to FIG. 15 will be omitted or simplified.

Referring to FIG. 16, the first active pattern 210a may be located on the buffer layer BUF. In addition, the first data line 410a may be located on the interlayer insulating layer ILD. The first data line 410a may overlap the first active pattern 210a in the plan view. That is, the first data line 410a may overlap the first active pattern 210a in a thickness direction (e.g., the third direction DR3).

Referring again to FIGS. 4, 5, 6, 7, 8, 9, 10, 11, 12, 13, 14, 15, and 16, in the display device DD according to embodiments of the present disclosure, the first pixel electrode PE1 of the first light-emitting element LED1 included in the first sub-pixel SPX1 might not overlap a driving gate node (e.g., the second connection pattern 420b of FIG. 10) connected to the gate electrode (e.g., the first-second gate electrode 310b of FIG. 8) of the driving transistor (e.g., the first transistor T1 of FIG. 9) included in the second sub-pixel SPX2 located adjacent to the first sub-pixel SPX1 in a plan view. The first and second sub-pixels SPX1 and SPX2 may emit light of different respective colors. The formation of a parasitic capacitor between the first pixel electrode PE1 of the first light-emitting element LED1 included in the first sub-pixel SPX1, and the driving gate node connected to the gate electrode of the driving transistor included in the second sub-pixel SPX2 can be minimized or reduced. In this case, defects, such as stains can be improved.

The present disclosure can be applied to various display devices. For example, the present disclosure is applicable to various display devices, such as display devices for vehicles, ships and aircraft, portable communication devices, display devices for exhibition or information transmission, medical display devices, and/or the like.

The foregoing is illustrative of embodiments and is not to be construed as limiting thereof. Although a few embodiments have been described, those skilled in the art will readily appreciate that many modifications are possible in the embodiments without materially departing from the novel teachings of the present disclosure. Accordingly, all such modifications are intended to be included within the scope of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, with functional equivalents thereof to be included therein.

What is claimed is:

1. A display device comprising:
a first sub-pixel comprising:
a first pixel circuit portion comprising a first active pattern, a first-first gate electrode of a first driving transistor partially overlapping the first active pattern, and a first connection pattern connected to the first-first gate electrode; and
a first light-emitting element electrically connected to the first pixel circuit portion, and comprising a first pixel electrode, a first light-emitting layer, and a first common electrode; and
a second sub-pixel adjacent to the first sub-pixel in a first direction, and comprising:
a second pixel circuit portion comprising a second active pattern, a first-second gate electrode of a second driving transistor partially overlapping the second active pattern, and a second connection pattern connected to the first-second gate electrode and not overlapping the first pixel electrode in plan view; and
a second light-emitting element electrically connected to the second pixel circuit portion, and comprising a second pixel electrode, a second light-emitting layer, and a second common electrode.

2. The display device of claim 1, wherein the first pixel electrode has a quadrilateral shape having a recessed corner part in plan view.

3. The display device of claim 1, wherein the second pixel electrode is adjacent to the first pixel electrode in a second direction crossing the first direction.

4. The display device of claim 1, wherein the first pixel circuit portion further comprises a first lower conductive pattern under the first active pattern, and partially overlapping the first active pattern in plan view,
wherein the second pixel circuit portion further comprises a second lower conductive pattern at a same layer as the first lower conductive pattern, and partially overlapping the second active pattern in plan view,
wherein a part of the first active pattern overlapping the first lower conductive pattern constitutes a first storage capacitor, and
wherein a part of the second active pattern overlapping the second lower conductive pattern constitutes a second storage capacitor.

5. The display device of claim 4, wherein the first active pattern defines a first through hole exposing a part of the first lower conductive pattern,
wherein the second active pattern defines a second through hole exposing a part of the second lower conductive pattern,
wherein the first connection pattern is connected to the first lower conductive pattern through a first contact hole overlapping the first through hole, and
wherein the second connection pattern is connected to the second lower conductive pattern through a second contact hole overlapping the second through hole.

6. The display device of claim 4, further comprising:
a first data line configured to receive a first data voltage, extending in a second direction crossing the first direction, and overlapping a first overlapping part of the first active pattern extending in the second direction in plan view; and
a second data line at a same layer as the first data line, configured to receive a second data voltage, extending in the second direction, and overlapping a second overlapping part of the second active pattern extending in the second direction in plan view.

7. The display device of claim 6, wherein the first overlapping part does not overlap the first lower conductive pattern in plan view, and
wherein the second overlapping part does not overlap the second lower conductive pattern in plan view.

8. The display device of claim 6, wherein the first and second data lines are at a same layer as the first and second connection patterns.

9. The display device of claim 1, wherein the second active pattern is symmetrical to the first active pattern.

10. The display device of claim 1, wherein the second connection pattern is symmetrical to the first connection pattern.

11. The display device of claim 1, wherein the first pixel electrode partially overlaps the second pixel circuit portion in plan view, and
wherein the second pixel electrode partially overlaps the first pixel circuit portion in plan view.

12. The display device of claim 1, wherein the first pixel electrode at least partially overlaps the first connection pattern in plan view.

13. The display device of claim 1, further comprising:
a driving voltage line under the first and second active patterns, configured to receive a driving voltage, and extending in the first direction,
wherein in the first pixel circuit portion, a part of the first active pattern constitutes a first hold capacitor together with a part of the driving voltage line, and
wherein in the second pixel circuit portion, a part of the second active pattern constitutes a second hold capacitor together with a part of the driving voltage line.

14. The display device of claim 1, wherein the first-first gate electrode is configured to receive a first data voltage through the first connection pattern, and
wherein the first-second gate electrode is configured to receive a second data voltage through the second connection pattern.

15. The display device of claim 1, wherein the first light-emitting layer and the second light-emitting layer comprise light-emitting materials configured to emit light of different respective colors.

16. The display device of claim 1, wherein each of the first and second active patterns comprises a metal oxide semiconductor.

17. A display device comprising:
a first active pattern above a substrate;
a second active pattern at a same layer as the first active pattern;
a first-first gate electrode of a first transistor above the first active pattern;
a first-second gate electrode of a second transistor at a same layer as the first-first gate electrode;
a first connection pattern above the first-first gate electrode, and connected to the first-first gate electrode;
a second connection pattern at a same layer as the first connection pattern, and connected to the first-second gate electrode;
a first pixel electrode above the first connection pattern, and not overlapping the second connection pattern in plan view; and
a second pixel electrode above the second connection pattern.

18. The display device of claim 17, wherein the first pixel electrode has a quadrilateral shape comprising a corner part that is recessed in plan view.

19. The display device of claim 17, further comprising:
a first lower conductive pattern under the first active pattern, and partially overlapping the first active pattern in plan view; and
a second lower conductive pattern at a same layer as the first lower conductive pattern, and partially overlapping the second active pattern in plan view,
wherein a part of the first active pattern overlapping the first lower conductive pattern constitutes a first storage capacitor, and
wherein a part of the second active pattern overlapping the second lower conductive pattern constitutes a second storage capacitor.

20. The display device of claim 19, wherein the first active pattern defines a first through hole exposing at least a part of the first lower conductive pattern,
wherein the second active pattern defines a second through hole exposing at least a part of the second lower conductive pattern,
wherein the first connection pattern is connected to the first lower conductive pattern through a first contact hole overlapping the first through hole, and
wherein the second connection pattern is connected to the second lower conductive pattern through a second contact hole overlapping the second through hole.

21. The display device of claim 19, further comprising:
a first data line configured to receive a first data voltage, extending in one direction, and overlapping a first overlapping part of the first active pattern extending in the one direction in plan view; and
a second data line at a same layer as the first data line, configured to receive a second data voltage, extending in the one direction, and overlapping a second overlapping part of the second active pattern extending in the one direction in plan view.

22. The display device of claim 21, wherein the first overlapping part does not overlap the first lower conductive pattern in plan view, and
wherein the second overlapping part does not overlap the second lower conductive pattern in plan view.

23. The display device of claim 17, wherein the second active pattern is symmetrical to the first active pattern, and
wherein the second active pattern is symmetrical to the first active pattern.

24. The display device of claim 17, wherein the first pixel electrode at least partially overlaps the first connection pattern in plan view.

25. The display device of claim 17, further comprising a driving voltage line under the first and second active patterns, configured to receive a driving voltage, and extending in one direction,
wherein a part of the first active pattern constitutes a first hold capacitor together with a part of the driving voltage line, and
wherein a part of the second active pattern constitutes a second hold capacitor together with another part of the driving voltage line.

26. The display device of claim 17, further comprising:
a first light-emitting layer above the first pixel electrode; and
a second light-emitting layer above the second pixel electrode,
wherein the first light-emitting layer and the second light-emitting layer comprise light-emitting materials configured to emit light of different respective colors.

27. The display device of claim 17, wherein the first-first gate electrode is configured to receive a first data voltage through the first connection pattern, and
wherein the first-second gate electrode is configured to receive a second data voltage through the second connection pattern.
